(19) United States
(12) Patent Application Publication
(10) Pub. No.: US 2026/0082572 A1
(43) Pub. Date: Mar. 19, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventors: Yusuke KINO, Kuwana Mie (JP); Toshitaka MIYATA, Yokkaichi Mie (JP)

(21) Appl. No.: 19/070,394

(22) Filed: Mar. 4, 2025

(30) Foreign Application Priority Data
Sep. 13, 2024 (JP) 2024-159434

(51) Int. Cl. H10B 43/40; H01L 23/00; H01L 25/00; H01L 25/065; H01L 25/18; H10B 41/27; H10B 41/41; H10B 43/27; H10B 80/00

(52) U.S. Cl. CPC H10B 43/40; H10B 41/27; H10B 41/41; H10B 43/27; H10B 80/00; H10W 90/00; H10W 80/211; H10W 80/312; H10W 80/327; H10W 90/792

(57) ABSTRACT

A semiconductor device includes a semiconductor substrate, a first transistor on the semiconductor substrate, an insulating layer above the semiconductor substrate in a first direction, a semiconductor layer provided on the insulating layer and partially overlapping the semiconductor substrate and the insulating layer in the first direction, a second transistor on the semiconductor layer, a first contact penetrating the insulating layer in the first direction such that the first contact is not in contact with the semiconductor layer, a second contact extending parallel to the first contact, and a memory cell array provided above the insulating layer and electrically connected to the second transistor through the second contact.

### CROSS-REFERENCE TO RELATED APPLICATION

This application is based upon and claims the benefit of priority from Japanese Patent Application No. 2024-159434, filed Sep. 13, 2024, the entire contents of which are incorporated herein by reference.

### FIELD

Embodiments described herein relate generally to a semiconductor device and a method of manufacturing a semiconductor device.

### BACKGROUND

A semiconductor device in which a plurality of transistors are provided on a semiconductor substrate is known. In order to achieve miniaturization of such a semiconductor device, an attempt to stack a plurality of semiconductor substrates on which a plurality of transistors are provided has been made. However, in order to make electrical connections to transistors on a lower layer side to an upper layer side, contacts or the like that penetrate a semiconductor substrate in which transistors on the upper layer side are provided need to be provided, and this leads to an increase in parasitic capacitance.

### BRIEF DESCRIPTION OF THE DRAWINGS

FIG. 1 is a block diagram illustrating a semiconductor device according to an embodiment.

FIG. 2 is an equivalent circuit diagram illustrating an example of a configuration of a memory cell array in the semiconductor device.

FIG. 3 is a circuit diagram illustrating an example of a configuration of a sense amplifier circuit and latch circuits in the semiconductor device.

FIG. 4 is a circuit diagram illustrating an example of a configuration of a row decoder in the semiconductor device.

FIG. 5 is a cross-sectional view illustrating a configuration example of the semiconductor device.

FIGS. 6A to 6C are cross-sectional views sequentially illustrating a part of a procedure of a method of manufacturing the semiconductor device.

FIGS. 7A and 7B are cross-sectional views sequentially illustrating a part of the procedure of the method of manufacturing the semiconductor device.

FIG. 8 is a cross-sectional view sequentially illustrating a part of the procedure of the method of manufacturing the semiconductor device.

FIG. 9 is a cross-sectional view sequentially illustrating a part of the procedure of the method of manufacturing the semiconductor device.

FIGS. 10A and 10B are cross-sectional views sequentially illustrating a part of the procedure of the method of manufacturing the semiconductor device.

FIG. 11 is a cross-sectional view sequentially illustrating a part of the procedure of the method of manufacturing the semiconductor device.

FIG. 12 is a cross-sectional view sequentially illustrating a part of the procedure of the method of manufacturing the semiconductor device.

FIGS. 13A to 13C are cross-sectional views sequentially illustrating a part of the procedure of the method of manufacturing the semiconductor device.

FIG. 14 is a cross-sectional view illustrating a configuration example of a semiconductor device according to a modification example.

### DETAILED DESCRIPTION

Embodiments provide a semiconductor device and a method of manufacturing a semiconductor device, in which a plurality of transistors can be stacked while reducing an increase in parasitic capacitance.

In general, according to one embodiment, a semiconductor device comprises a semiconductor substrate; a first transistor on the semiconductor substrate; an insulating layer above the semiconductor substrate; a semiconductor layer provided on the insulating layer and having a smaller area than the semiconductor substrate and the insulating layer; a second transistor on the semiconductor layer; a first contact penetrating the insulating layer such that the first contact does not overlap the semiconductor layer when viewed from above; a second contact extending parallel to the first contact; and a memory cell array provided above the insulating layer and electrically connected to the second transistor through the second contact.

Hereinafter, embodiments of the present disclosure will be described with reference to the drawings. The present disclosure is not limited to the embodiments described below. In addition, components in the following embodiment include those that are easily conceivable by persons skilled in the art or substantial equivalents thereof.

### Circuit Configuration of Semiconductor Device

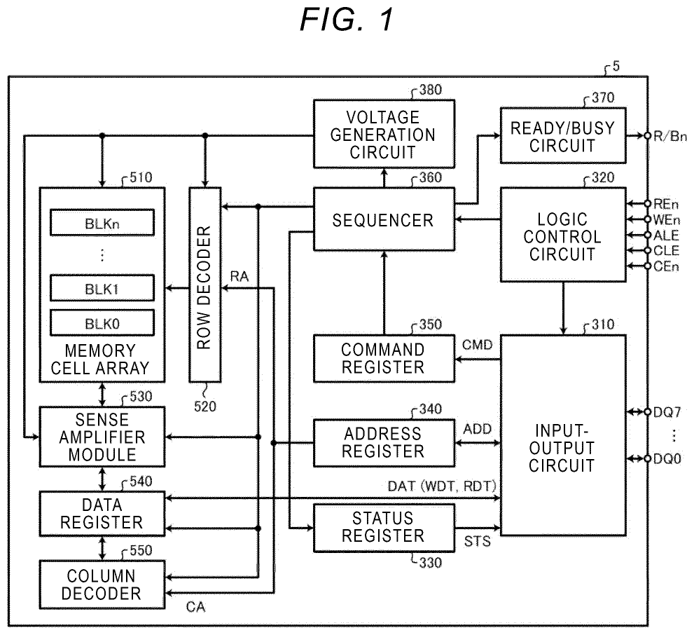

First, a circuit configuration of a semiconductor device 1 according to an embodiment will be described with reference to FIGS. 1 to 4.

### (Overall Configuration of Semiconductor Device)

FIG. 1 is a block diagram illustrating the semiconductor device 1. As illustrated in FIG. 1, the semiconductor device 1 includes an input-output circuit 310, a logic control circuit 320, a status register 330, an address register 340, a command register 350, a sequencer 360, a ready/busy circuit 370, a voltage generation circuit 380, a memory cell array 510, a row decoder 520, a sense amplifier module 530, a data register 540, and a column decoder 550.

The input-output circuit 310 controls an input and an output of a signal DQ to and from an external apparatus such as a memory controller (not illustrated) that controls the semiconductor device 1. The input-output circuit 310 includes an input circuit and an output circuit (not illustrated).

The input circuit transmits data DAT such as write data WDT received from an external apparatus to the data register 540, transmits an address ADD to the address register 340, and transmits a command CMD to the command register 350.

The output circuit transmits status information STS received from the status register 330, the data DAT such as read data RDT received from the data register 540, and the address ADD received from the address register 340 to the external apparatus.

The logic control circuit 320 receives, for example, a chip enable signal CEn, a command latch enable signal CLE, an address latch enable signal ALE, a write enable signal WEn, and a read enable signal REn from the external apparatus. In addition, the logic control circuit 320 controls the input-output circuit 310 and the sequencer 360 according to the received signals.

The status register 330 temporarily stores, for example, the status information STS in a write operation, a read operation, and an erase operation of data, and notifies whether an operation normally ends to the external apparatus.

The address register 340 temporarily stores the address ADD received from the external apparatus through the input-output circuit 310. In addition, the address register 340 transmits a row address RA to the row decoder 520, and transmits a column address CA to the column decoder 550.

The command register 350 temporarily stores the command CMD received from the external apparatus through the input-output circuit 310, and transmits the command CMD to the sequencer 360.

The sequencer 360 controls an overall operation of the semiconductor device 1. More specifically, the sequencer 360 controls, for example, the status register 330, the ready/busy circuit 370, the voltage generation circuit 380, the row decoder 520, the sense amplifier module 530, the data register 540, and the column decoder 550 to execute the write operation, the read operation, the erase operation, and the like according to the command CMD stored in the command register 350.

The ready/busy circuit 370 transmits the ready/busy signal R/Bn to the external apparatus according to an operating status of the sequencer 360.

The voltage generation circuit 380 generates voltages required for the write operation, the read operation, and the erase operation according to the control of the sequencer 360, and supplies the generated voltages to, for example, the memory cell array 510, the row decoder 520, and the sense amplifier module 530. The row decoder 520 and the sense amplifier module 530 apply the voltages supplied from the voltage generation circuit 380 to memory cells in the memory cell array 510.

The memory cell array 510 includes a plurality of blocks BLK (BLK0 to BLKn) where n represents an integer of 2 or more. The block BLK is a set including a plurality of memory cells associated with bit lines and word lines, and is, for example, a unit of erasing data. The memory cell is formed by, for example, a transistor and stores nonvolatile data.

By including the memory cells, the semiconductor device 1 forms, for example, a NAND nonvolatile memory.

The row decoder 520 decodes the row address RA. In addition, the row decoder 520 selects any of the blocks BLK based on the decoding result. In addition, the row decoder 520 applies a necessary voltage to the block BLK.

The sense amplifier module 530 senses data read from the memory cell array 510 during the read operation. In addition, the sense amplifier module 530 transmits the read data RDT to the data register 540. During the write operation, the sense amplifier module 530 transmits the write data WDT to the memory cell array 510.

The data register 540 includes a plurality of latch circuits. The latch circuit stores the write data WDT and the read data RDT. For example, in the write operation, the data register 540 temporarily stores the write data WDT received from the input-output circuit 310, and transmits the write data WDT to the sense amplifier module 530. In addition, for example, in the read operation, the data register 540 temporarily stores the read data RDT received from the sense amplifier module 530, and transmits the read data RDT to the input-output circuit 310.

For example, during the write operation, the read operation, and the erase operation, the column decoder 550 decodes the column address CA, and selects the latch circuit in the data register 540 according to the decoding result.

A circuit group disposed around the memory cell array 510 will be referred to as a peripheral circuit. The peripheral circuit includes at least the row decoder 520, the sense amplifier module 530, the data register 540, and the column decoder 550. The peripheral circuit may include the status register 330, the address register 340, the command register 350, and the sequencer 360, and may further include the input-output circuit 310, the logic control circuit 320, the ready/busy circuit 370, and the voltage generation circuit 380.

This way, the semiconductor device 1 includes the memory cell array 510 that includes a plurality of memory cells and the peripheral circuit that operates the plurality of memory cells.

### (Circuit Configuration of Memory Cell Array)

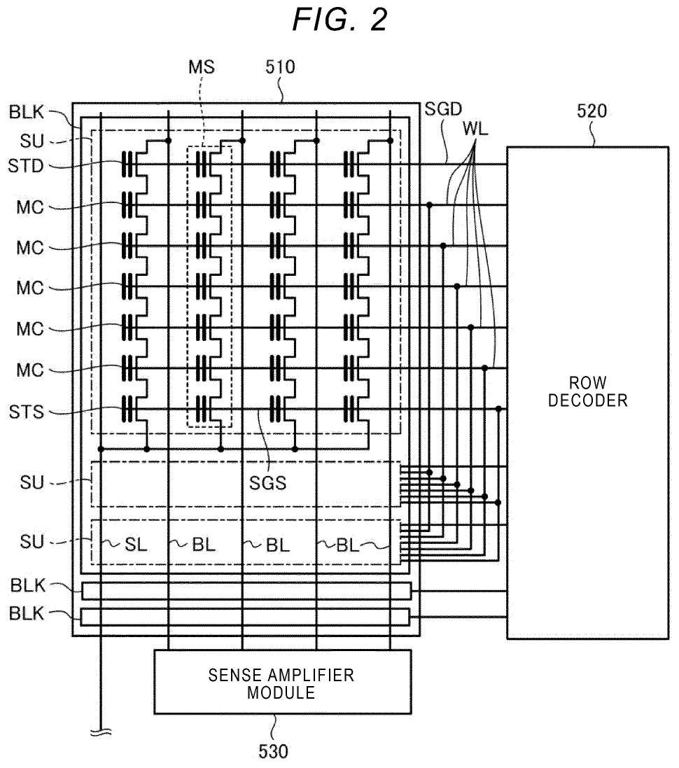

FIG. 2 is an equivalent circuit diagram illustrating an example of a configuration of the memory cell array 510 in the semiconductor device 1.

The memory cell array 510 includes the plurality of blocks BLK as described above. Each of the plurality of blocks BLK includes a plurality of string units SU. Each of the plurality of string units SU includes a plurality of memory strings MS. Each of first ends of the plurality of memory strings MS is connected to the peripheral circuit such as the sense amplifier module 530 through a bit line BL. Each of second ends of the plurality of memory strings MS is connected to the peripheral circuit through a common source line SL.

The memory strings MS includes a drain-side select transistor STD, a plurality of memory cells MC, and a source-side select transistor STS that are connected in series between the bit line BL and the source line SL. Hereinafter, the drain-side select transistor STD and the source-side select transistor STS will also be referred to as the select transistors (STD, STS).

The memory cell MC is, for example, a field effect transistor (FET) including a gate insulating layer and a charge storage layer. A threshold voltage of the memory cell MC changes depending on the amount of charge in the charge storage layer. By providing one or a plurality of threshold voltages, the memory cell MC can store data of one bit or a plurality of bits. A word line WL is connected to each of gate electrodes of the plurality of memory cells MC corresponding to one memory string MS. These word lines WL are connected in common to all of the memory strings MS in one block BLK.

The select transistors (STD, STS) are, for example, field effect transistors. Select gate lines (SGD, SGS) are connected to gate electrodes of the select transistors (STD, STS), respectively. The drain selection line SGD connected to the drain-side select transistor STD is provided corresponding to the string unit SU, and is connected to in common to all of memory strings MS in one string unit SU. The source selection line SGS connected to the source-side select transistor STS is connected in common to all of memory strings MS in one block BLK.

Each of first ends of the word line WL and the select gate lines (SGD, SGS) is connected to the peripheral circuit such as the row decoder 520.

### (Circuit Configuration of Sense Amplifier Module)

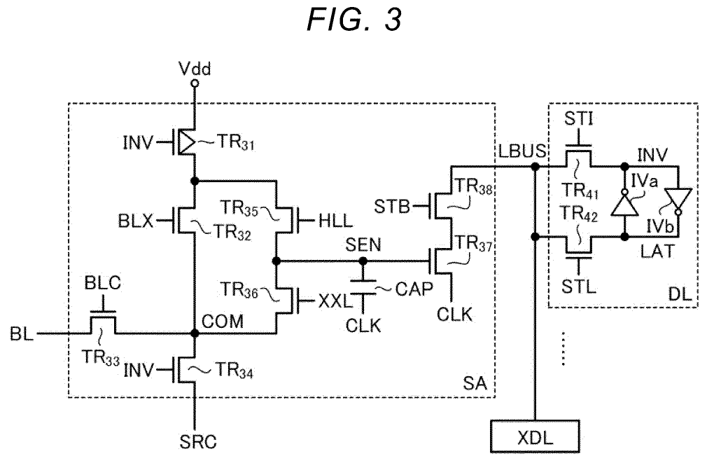

FIG. 3 is a circuit diagram illustrating an example of a configuration of a sense amplifier circuit SA and latch circuits DL and XDL in the semiconductor device 1.

The sense amplifier module 530 is formed by a plurality of sense amplifier circuits SA provided for each of the bit lines BL. For example, in the read operation, each of the sense amplifier circuits SA senses data read to the corresponding bit line BL, and determines whether the read data is “0” or “1”.

In addition, the data register 540 includes the plurality of latch circuits DL and XDL corresponding to each of the plurality of sense amplifier circuits SA. The latch circuit XDL is also provided for each of the bit lines BL. On the other hand, a plurality of the latch circuits DL are provided for the corresponding sense amplifier circuit SA. In this case, the number of the latch circuits DL is designed, for example, based on the number of bits in data that can be stored in one memory cell MC. The latch circuits DL and XDL temporarily store data relating to the corresponding bit line BL.

FIG. 3 illustrates one sense amplifier circuit SA in the sense amplifier module 530 and one latch circuit DL and one latch circuit XDL in the data register 540. A plurality of control signals supplied to the sense amplifier circuit SA and the like are controlled by the sequencer 360.

As illustrated in FIG. 3, the sense amplifier circuit SA includes transistors TR31 to TR38 and a capacitor CAP. In the drawing, the transistor TR31 is a low breakdown voltage P-channel metal-oxide-semiconductor (MOS) transistor. In addition, the transistors TR32 to TR38 are low breakdown voltage N-channel MOS transistors.

The low breakdown voltage CMOS transistors including the low breakdown voltage P-channel MOS transistor and the low breakdown voltage N-channel MOS transistor are transistors to which a relatively low voltage is applied, and are also called low voltage (LV) or very low voltage (VLV) MOS transistors.

A first end of the transistor TR31 is connected to a power supply line through which a power supply voltage Vdd is supplied, and a gate electrode of the transistor TR31 is connected to a node INV. A first end of the transistor TR32 is connected to a second end of the transistor TR31, a second end of the transistor TR32 is connected to a node COM, and a control signal BLX is input to a gate electrode of the transistor TR32. A first end of the transistor TR33 is connected to the node COM, a second end of the transistor TR33 is connected to the corresponding bit line BL, and a control signal BLC is input to a gate electrode of the transistor TR33.

A first end of the transistor TR34 is connected to the node COM, a second end of the transistor TR34 is connected to a node SRC, and a gate electrode of the transistor TR34 is connected to the node INV.

A first end of the transistor TR35 is connected to the second end of the transistor TR31, a second end of the transistor TR35 is connected to a node SEN, and a control signal HLL is input to a gate electrode of the transistor TR35. A first end of the transistor TR36 is connected to the node SEN, a second end of the transistor TR36 is connected to the node COM, and a control signal XXL is input to a gate electrode of the transistor TR36.

A clock CLK is input to a first end of the transistor TR37, and a gate electrode of the transistor TR37 is connected to the node SEN. A first end of the transistor TR38 is connected to a second end of the transistor TR37, a second end of the transistor TR38 is connected to a bus LBUS, and a control signal STB is input to a gate electrode of the transistor TR38. A first end of the capacitor CAP is connected to the node SEN, and the clock CLK is input to a second end of the capacitor CAP.

The latch circuits DL includes inverters IVa and IVb and transistors TR41 and TR42. In the drawing, the transistors TR41 and TR42 are low breakdown voltage N-channel MOS transistors. Hereinafter, the transistors TR41 and TR42 in the data register 540 will also simply be referred to as the transistors TR.

FIG. 3 illustrates one latch circuits DL, and the other latch circuits DL also have the same configuration.

In the inverter IVa, an input terminal is connected to the node LAT, and an output terminal is connected to the node INV. In the inverter IVb, an input terminal is connected to the node INV, and an output terminal is connected to the node LAT.

In the transistor TR41, a first end is connected to the node INV, a second end is connected to the bus LBUS, and a control signal STI is input to a gate electrode. In the transistor TR42, a first end is connected to the node LAT, a second end is connected to the bus LBUS, and a control signal STL is input to a gate electrode.

The latch circuit XDL has, for example, substantially the same configuration as the latch circuits DL, and is connected to the bus LBUS such that data can be transmitted and received to and from the sense amplifier circuit SA and the latch circuits DL. In addition, the latch circuit XDL is connected to the above-described input-output circuit 310, and is used for input and output of data to and from the sense amplifier circuit SA and the input-output circuit 310.

In addition, the latch circuit XDL is also used for a cache operation of the semiconductor device 1. That is, even when all of the latch circuits DL corresponding to the sense amplifier circuit SA are being used, as long as the latch circuit XDL is free, the semiconductor device 1 can receive data from the external apparatus.

This way, the sense amplifier circuit SA and the latch circuits DL and XDL belonging to the peripheral circuit include the plurality of transistors TR.

Next, an operation of the sense amplifier circuit SA having the above-described configuration will be simply described.

When charge is injected to the memory cell MC to increase a threshold voltage as an example of writing data into the memory cell MC, an “H” level (data of “1”) is stored in the node INV of the latch circuits DL. As a result, the transistor TR34 is turned on, and the bit line BL is set to 0 V.

When charge is not injected to the memory cell MC not to change a threshold voltage as another example of writing data into the memory cell MC, an “L” level (data of “0”) is stored in the node INV of the latch circuits DL. As a result, the transistor TR31 is turned on, and a predetermined positive voltage is applied to the bit line BL.

During the read operation, the node INV is set to the “L” level, and the transistor TR31 is turned on. In addition, the bit line BL is precharged by the transistor TR31 through the transistors TR41 and TR42. In addition, the transistor TR35 is turned on, and the node SEN is charged up to a predetermined voltage.

Next, the transistor TR35 is turned off, the signal XXL is set to the “H” level, and the transistor TR36 is turned on. As a result, when the corresponding memory cell MC is turned on, the voltage of the node SEN decreases, the transistor TR37 is turned off. On the other hand, when the corresponding memory cell MC is turned off, the voltage of the node SEN is maintained at the “H”level, the transistor TR37 is turned on.

In addition, the transistor TR38 is turned on by the signal STB, and the voltage corresponding to the on/off of the transistor TR37 is read to the bus LBUS and is stored in the latch circuits DL.

The circuit configuration of the sense amplifier circuit SA and the latch circuits DL and XDL illustrated in FIG. 3 is merely an example, and the sense amplifier circuit SA and the latch circuits DL and XDL can adopt various configurations other than the above-described configuration. Therefore, the number and types of the transistors TR in each of the sense amplifier circuit SA and the latch circuits DL and XDL can also vary in many ways. For example, the sense amplifier circuit SA and the latch circuits DL and XDL may also include a high breakdown voltage P-channel MOS transistor, a high breakdown voltage N-channel MOS transistor, or the like.

### (Circuit Configuration of Row Decoder)

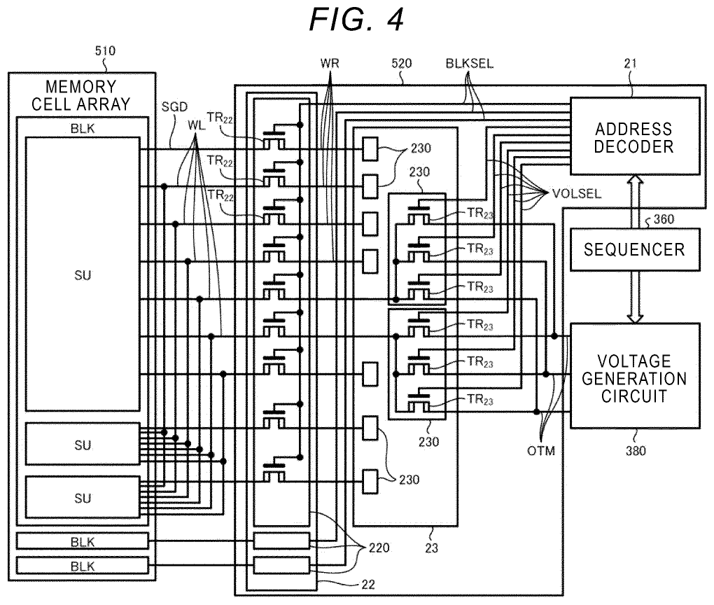

FIG. 4 is a circuit diagram illustrating an example of a configuration of the row decoder 520 in the semiconductor device 1.

As illustrated in FIG. 4, the row decoder 520 includes an address decoder 21, a block selection circuit 22, and a voltage selection circuit 23.

The address decoder 21 includes a plurality of block selection lines BLKSEL and a plurality of voltage selection lines VOLSEL.

The address decoder 21 refers to address data of the address register 340 in the above-described peripheral circuit, for example, in accordance with a control signal from the sequencer 360.

In addition, the address decoder 21 decodes the referred address data, turns on the transistor TR22 and the transistor TR23 corresponding to the address data, and turns off the other transistors TR22 and the transistors TR23. The transistor TR22 and the transistor TR23 are transistors in the block selection circuit 22 and the voltage selection circuit 23 described below, respectively.

In addition, the address decoder 21 sets the voltages of the block selection lines BLKSEL and the voltage selection lines VOLSEL corresponding to the address data to, for example, the “H” state, and sets the other voltages to the “L” state. Voltages applied to wirings of the block selection circuit 22 and the voltage selection circuit 23 are reversed depending on whether to use an N-channel type transistor or a P-channel type transistor in these circuits. The above-described voltages are examples when the transistors are N-channel type transistors.

In the example of FIG. 4, in the address decoder 21, one block selection lines BLKSEL is provided for one block BLK in the memory cell array 510. However, this configuration can be appropriately changed. For example, one block selection lines BLKSEL may be provided for two or more blocks BLK.

The block selection circuit 22 includes a plurality of block selection units 220 corresponding to each of the blocks BLK of the memory cell array 510. Each of the plurality of block selection units 220 includes a plurality of transistors TR22 corresponding to the word line WL and the select gate lines (SGD, SGS).

The transistor TR22 is a high breakdown voltage N-channel MOS transistor and functions as a block driving transistor. Each of the drain electrodes of the transistors TR22 is electrically connected to the corresponding word line WL or the corresponding select gate lines (SGD, SGS). Each of the source electrodes of the transistors TR22 is electrically connected to a voltage output terminal OTM through a wiring WR and the voltage selection circuit 23. The gate electrodes of the transistors TR22 are connected in common to the corresponding block selection line BLKSEL.

In addition, the block selection circuit 22 further includes a plurality of transistors (not illustrated). These plurality of transistors are high breakdown voltage CMOS transistors connected between the select gate lines (SGD, SGS) and a ground voltage supply terminal. The plurality of transistors electrically connect the select gate lines (SGD, SGS) in non-selected blocks BLK in the memory cell array 510 to the ground voltage supply terminal. The plurality of word lines WL in the non-selected blocks BLK are in a floating state.

The voltage selection circuit 23 includes a plurality of voltage selection units 230 corresponding to the word line WL and the select gate lines (SGD, SGS). Each of the plurality of voltage selection units 230 includes a plurality of transistors TR23.

The transistor TR23 is a high breakdown voltage N-channel MOS transistor and functions as a voltage select transistor. Each of drain terminals of the transistors TR23 is electrically connected to the corresponding word line WL or the corresponding select gate lines (SGD, SGS) through the wiring WR and the block selection circuit 22. Each of source terminals is electrically connected to the corresponding voltage output terminal OTM. Each of gate electrodes is connected to the corresponding voltage selection line VOLSEL.

The high breakdown voltage CMOS transistors including the high breakdown voltage P-channel MOS transistor and the high breakdown voltage N-channel MOS transistor are transistors to which a relatively high voltage is applied, and are also called high voltage (HV) MOS transistors.

This way, the row decoder 520 belonging to the peripheral circuit include the plurality of transistors TR22 and TR23. It should be noted that the circuit configuration of the row decoder 520 illustrated in FIG. 4 is an example, and the numbers and types of the transistors TR22 and TR23 and the like in the row decoder 520 can also vary in many ways.

### Physical Configuration of Semiconductor Device

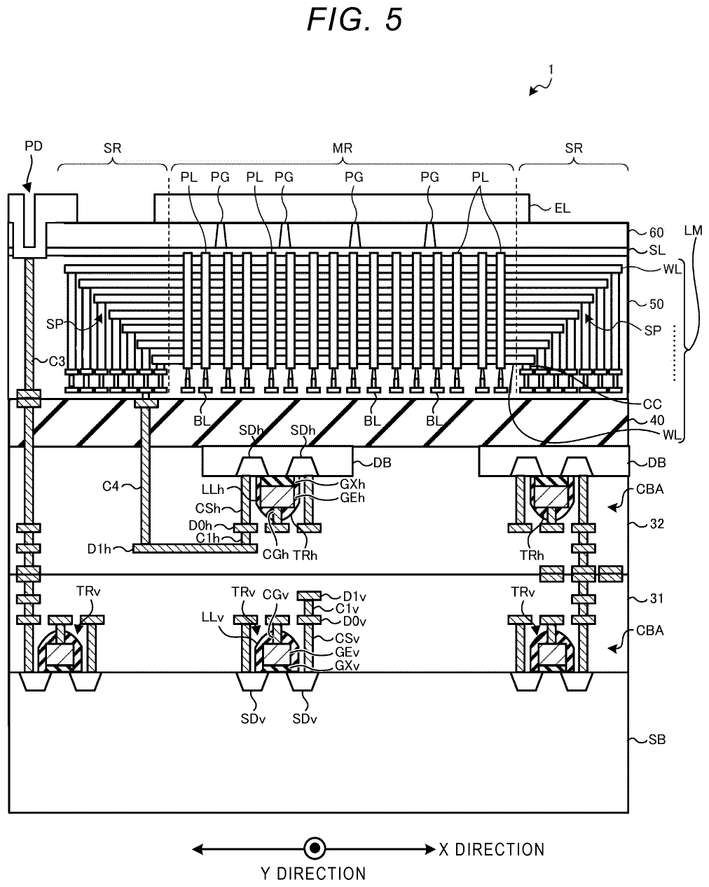

Next, an example of a physical configuration of the semiconductor device 1 will be described using FIG. 5.

FIG. 5 is a cross-sectional view illustrating a configuration example of the semiconductor device 1. It should be noted that FIG. 5 does not illustrate hatching of a partial configuration in consideration of easy understanding of the drawing.

An X direction and a Y direction illustrated in FIG. 5 are directions perpendicular to each other. In addition, the X direction in FIG. 5 is a direction perpendicular to an extending direction of gate electrodes GEv and GEh described below, that is, a direction along gate lengths of the gate electrodes GEv and GEh. In addition, the Y direction is a direction along gate widths of the gate electrodes GEv and GEh.

As illustrated in FIG. 5, the semiconductor device 1 includes a peripheral circuit CBA, a stacked body LM including a plurality of word lines WL where a pillar PL is formed, a source line SL, and an electrode layer EL in this order above a semiconductor substrate SB. In the following description, it is assumed that a side where the semiconductor substrate SB is disposed is a lower side of the semiconductor device 1.

The semiconductor substrate SB is, for example, a diced silicon substrate. A plurality of semiconductor layers DB having a smaller area than an upper surface of the semiconductor substrate SB are disposed above the semiconductor substrate SB. These semiconductor layers DB are, for example, polysilicon layers.

The peripheral circuit CBA where a plurality of transistors TRv and TRh are stacked in multiple stages is disposed between the semiconductor substrate SB and the plurality of semiconductor layers DB. Among the transistors TRv and TRh, the transistor TRv is disposed on the semiconductor substrate SB, and the transistor TRh is disposed on a surface of the semiconductor layer DB facing the semiconductor substrate SB.

That is, in a state where the transistors TRv are reversed upside down, the transistors TRh are disposed above the transistors TRv to face the transistors TRv on the semiconductor substrate SB. It should be noted that the transistors TRh and the transistors TRv may be disposed at positions where the transistors TRh and the transistors TRv overlap each other in an up-down direction as illustrated in FIG. 5, or may be disposed at positions where some or all of the transistors TRh and the transistors TRv do not overlap each other in the up-down direction.

An insulating layer 31 that covers the transistor TRv on the semiconductor substrate SB is provided on the semiconductor substrate SB. An insulating layer 32 that covers the transistor TRh on the semiconductor layer DB is provided on the semiconductor layer DB. The semiconductor substrate SB and the semiconductor layers DB are bonded to each other through the insulating layers 31 and 32 such that the plurality of transistors TRv and TRh are stacked in multiple stages.

The transistor TRv on the semiconductor substrate SB includes a source/drain region SDv, a gate insulating layer GXv, a gate electrode GEv, and a liner layer LLv.

The source/drain region SDv is provided distant from the semiconductor substrate SB, and is a region where impurity of a predetermined conductivity type is diffused. The gate electrode GEv is disposed through the gate insulating layer GXv at a position on the semiconductor substrate SB straddling the source/drain regions SDv distant from each other. The entirety of the gate electrode GEv and the gate insulating layer GXv is covered with the liner layer LLv. The liner layer LLv is, for example, a silicon oxide layer, a silicon nitride layer, or a silicon oxynitride layer or has a multi-layer structure where some of the layers are combined.

The transistors TRv are formed by, for example, low voltage (LV, VLV) MOS transistors to which a relatively low voltage is applied, and include, for example, the sense amplifier module 530 (refer to FIG. 3) and circuits, such as the input-output circuit 310, the logic control circuit 320, and the ready/busy circuit 370 (refer to FIG. 1), that function as an interface with the external apparatus in the peripheral circuit CBA.

The transistors TRv that are used as the circuits functioning as the interface require a high speed operation, and are preferably configured to have a relatively short gate length. Therefore, for example, a tungsten layer or a nickel-platinum silicide layer is used as the gate electrodes GEv of the transistors TRv. The tungsten layers or the nickel-platinum silicide layers require a high speed operation, and are suitable as a gate electrode material of a low voltage MOS transistor having a relatively short gate length.

As described above, in FIG. 5, distances of the gate electrodes GEv and GEh of the individual transistors TRv and TRh in the X direction correspond to the gate lengths of the gate electrodes GEv and GEh in the transistors TRv and TRh, and distances of the gate electrodes GEv and GEh in the Y direction correspond to the gate widths of the gate electrodes GEv and GEh in the transistors TRv and TRh.

The source/drain regions SDv and the gate electrodes GEv of the transistors TRv are connected to contacts CSv and CGv extending in the insulating layer 31 that covers the transistors TRv, respectively. A wiring layer D0v, a via C1v, a wiring layer D1v, and . . . disposed in the insulating layer 31 in order from the transistor TRv side are connected to the contact contacts CSv and CGv, respectively. As a result, among the plurality of transistors TRv, some transistors TRv are connected to the transistors TRh provided facing the transistors TRv, and some transistors TRv are connected to the electrode layer EL through a contact C3 extending in the up-down direction in the same hierarchy as the stacked body LM.

The transistor TRh on the semiconductor layer DB includes a source/drain region SDh, a gate insulating layer GXh, a gate electrode GEh, and a liner layer LLh.

The source/drain region SDh is provided distant from the semiconductor layer DB, and is a region where impurity of a predetermined conductivity type is diffused. The gate electrode GEh is disposed through the gate insulating layer GXh at a position on the semiconductor layer DB straddling the source/drain regions SDh distant from each other. The entirety of the gate electrode GEh and the gate insulating layer GXh is covered with the liner layer LLh. The liner layer LLh is, for example, a silicon oxide layer, a silicon nitride layer, or a silicon oxynitride layer or has a multi-layer structure where some of the layers are combined.

The transistors TRh are formed by, for example, high voltage (HV) MOS transistors to which a relatively high voltage is applied. It should be noted that some of the transistors TRh may be configured as low voltage (VLV) MOS transistors. The transistors TRh on the semiconductor layers DB include, for example, the row decoder 520 (refer to FIG. 4) in the peripheral circuit CBA.

The transistors TRh for a high voltage do not require a high speed operation unlike the low voltage MOS transistor. Therefore, as the gate electrode GEh of the transistor TRh, a gate electrode material such as a tungsten silicide layer or a tungsten nitride layer that is relatively easily processed may be used as compared to a tungsten layer or a nickel-platinum silicide layer used as the gate electrode material of the low voltage MOS transistor.

In addition, the transistors TRh to which a high voltage is applied have a higher breakdown voltage than, for example, the above-described transistor TRv for a low voltage.

Specifically, the gate insulating layers GXh of the transistors TRh are thicker than, for example, the gate insulating layers GXv of the above-described transistors TRv. In addition, the gate electrodes GEh of the transistors TRh have a longer gate length than, for example, the gate electrodes GEv of the above-described transistors TRv.

In the monocrystalline semiconductor substrate SB, a higher carrier mobility can be obtained as compared to the semiconductor layer DB such as a polysilicon layer. Accordingly, among the transistor TRv for a low voltage and the transistor TRh for a high voltage, the transistor TRv for a low voltage that requires a high speed operation for some uses is provided on the semiconductor substrate SB such that the operation performance of the transistor TRv can be improved.

Contacts CSh and CGh extending in the insulating layer 32 that covers the transistors TRh are connected to the source/drain regions SDh and the gate electrodes GEh of the transistors TRh. A wiring layer D0h, a via C1h, a wiring layer D1h, and . . . disposed in the insulating layer 32 in order from the transistor TRh side are connected to the contact contacts CSh and CGh, respectively. As a result, among the plurality of transistors TRh, some transistors TRh are connected to the transistors TRv provided facing the transistors TRh, and some transistors TRh are connected to a contact CC described below that supply power to the word line WL through a contact C4 extending toward the stacked body LM side.

In addition to the transistors TRv and TRh, the above-described peripheral circuit CBA may include the contacts CSv and CGv, the wiring layer D0v, the via C1v, the wiring layer D1v, and the like, and the contacts CSh and CGh, the wiring layer D0h, the via C1h, the wiring layer D1h, and the like that are connected to the transistors TRv and TRh, respectively.

An insulating layer 40 that covers an upper surface of the insulating layer 32 including the plurality of semiconductor layers DB is disposed above the peripheral circuit CBA. The insulating layer 40 has a larger area than at least the above-described semiconductor layer DB, and covers the entirety of the semiconductor substrate SB where the peripheral circuit CBA is provided.

In addition, the insulating layer 40 is, for example, a silicon oxide layer such as a undoped silicate glass (NSG) layer, and it is preferable that a carbon concentration in at least a portion from a surface side in contact with the semiconductor layer DB to a predetermined thickness is lower than the other portions of the insulating layer 40. The carbon concentration in the low carbon concentration portion of the insulating layer 40 is preferably, for example, 1×1018 atoms/cm3 or less. It should be noted that the entirety of the insulating layer 40 has the low carbon concentration. As a result, a leakage current from the semiconductor layer DB where the transistor TRh is provided can be reduced.

The stacked body LM where the plurality of word lines WL are stacked distant from each other is disposed above the peripheral circuit CBA through the insulating layer 40. One or more select gate lines SGS (refer to FIG. 2) may be stacked on the lower layer side of the plurality of word lines WL, that is, the peripheral circuit CBA side. One or more select gate lines SGD (refer to FIG. 2) may be stacked on the upper layer side of the plurality of word lines WL, that is, the side opposite to the peripheral circuit CBA. The stacked body LM including the plurality of word lines WL is covered with the insulating layer 50, and the peripheral circuit CBA is joined to the insulating layer 50 through the above-described insulating layer 40.

The insulating layer 50 is also spread around the stacked body LM. In the peripheral insulating layer 50, the contact C3 extending in the insulating layer 50 is disposed in a stacking direction of the plurality of word lines WL. The contact C3 is electrically connected to the above-described some transistors TRv provided on the semiconductor substrate SB. As a result, the peripheral circuit CBA and the source line SL are electrically connected to each other.

A memory region MR is disposed in a center portion of the stacked body LM in the X direction, and a stepwise region SR is disposed at both end portions of the stacked body LM in the X direction.

In the memory region MR, a plurality of pillars PL that penetrate the word lines WL and the like in the stacking direction are disposed. A memory cell MC (refer to FIG. 2) is formed at an intersection between the pillar PL and the word line WL. Each of the select gate lines STD and STS (refer to FIG. 2) is formed at an intersection between the pillar PL and the select gate lines SGD and SGS. As a result, the semiconductor device 1 forms, for example, a three-dimensional nonvolatile memory where the memory cells MC are three-dimensionally disposed in the memory region MR.

This way, the memory region MR is an example of a physical configuration corresponding to the above-described memory cell array 510 (refer to FIG. 2). In addition, the pillar PL is an example of a physical configuration corresponding to the above-described memory string MS (refer to FIG. 2) where the memory cells MC and the like are connected in series.

In the physical configuration of the semiconductor device 1, the pillar PL is electrically connected to the sense amplifier module 530 of the peripheral circuit CBA through the bit line BL and the like disposed below the pillar PL.

In the stepwise region SR, a step portion SP obtained by processing both end portions of the plurality of word lines WL stepwise is disposed. As a result, the widths of both the end portions of the plurality of word lines WL and the like are spread toward the upper source line SL. The contacts CC are connected to the layers of the plurality of word lines WL in the step portion SP, respectively.

Through the contacts CC, the word lines WL and the like stacked in multiple layers are individually led out. That is, a write voltage, a read voltage, and the like are applied from the contacts CC to the memory cells MC in the memory region MR in the center portion in an extending direction of the plurality of word lines WL through the word lines WL at the same height positions as the memory cells MC.

Various voltages applied from the contacts CC to the memory cells MC are controlled by the row decoder 520 of the peripheral circuit CBA that is electrically connected to the contacts CC.

The source line SL is disposed above the stacked body LM including the plurality of word lines WL. The electrode layer EL is disposed on the source line SL through an insulating layer 60 such as a silicon oxide layer. A plurality of plugs PG are disposed in the insulating layer 60, and the electrode layer EL and the source line SL are electrically connected to each other. In addition, the electrode layer EL includes a pad region PD that penetrates the insulating layer 60 and the source line SL and has electrical connection to the contact C3 in a partial region.

With the above-described configuration, a source voltage is applied from the outside of the semiconductor device 1 to the source line SL through the electrode layer EL.

Incidentally, some of the above-described transistors TRv are connected to the contact C3 in the same hierarchy as the stacked body LM through the contact CSv, the wiring layer D0v, the via C1v, the wiring layer D1v, and . . . In addition, some of the above-described transistors TRh are connected to the contact C4 leading to the contact CC of the stacked body LM through the contact CSh, the wiring layer D0h, the via C1h, the wiring layer D1h, and . . .

At this time, the contact CSv, the wiring layer D0v, the via C1v, the wiring layer D1v, . . . , and the contact C3, and the contact CSh, the wiring layer D0h, the via C1h, the wiring layer D1h, . . . , and the contact C4 extend in the insulating layers 31, 32, and 40. As a result, insulating characteristics from the peripheral configuration are maintained, and occurrence of a parasitic capacitance is prevented.

### Method of Manufacturing Semiconductor Device

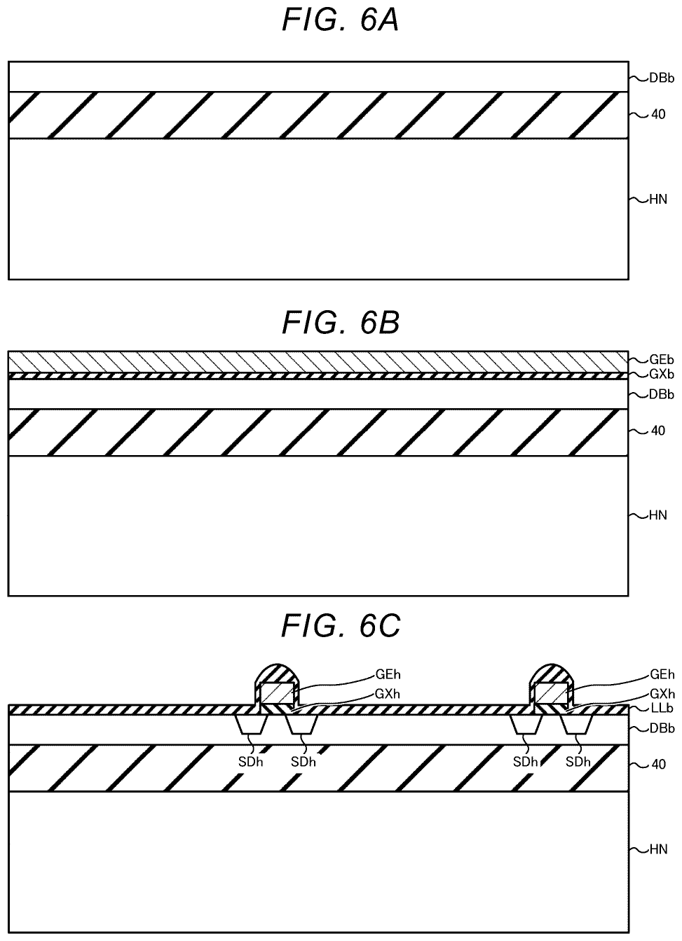

Next, a method of manufacturing the semiconductor device 1 will be described using FIGS. 6A to 13C. FIGS. 6A to 13C are cross-sectional views sequentially illustrating a part of a procedure of the method of manufacturing the semiconductor device 1.

As illustrated in FIG. 6A, the insulating layer 40 and a semiconductor layer DBb are formed in this order on a supporting substrate HN. The supporting substrate HN is, for example, a semiconductor substrate such as a silicon substrate, the insulating layer 40 is a silicon oxide layer or the like, and the semiconductor layer DBb is a polysilicon layer or the like. It should be noted that the supporting substrate HN may be an insulating substrate such as a ceramic substrate or may be a conductive substrate or the like. In addition, the semiconductor layer DBb is a layer that is subsequently patterned to form the semiconductor layer DB where the transistor TRh is formed.

In addition, it is preferable that the insulating layer 40 is formed as a silicon oxide layer such as a high-quality NSG layer where the carbon concentration is low, for example, using a thermal chemical vapor deposition (CVD) method. By using the thermal CVD or the like, for example, a high-quality NSG layer where the carbon concentration is, for example, 1×1018 atoms/cm3 or less can be formed.

As illustrated in FIG. 6B, an insulating layer GXb and a conductive layer GEb are formed in this order on the semiconductor layer DBb. The insulating layer GXb is, for example, a silicon oxide layer or a High-k insulating layer such as a hafnium oxide layer or a zirconia layer, and is a layer that is subsequently patterned to form the gate insulating layer GXh of the transistor TRh. The conductive layer GEb is, for example, a tungsten silicide layer or a tungsten nitride layer, and is a layer that is subsequently patterned to form the gate electrode GEh of the transistor TRh.

As illustrated in FIG. 6C, the insulating layer GXb and the conductive layer GEb are patterned to form the gate insulating layer GXh and the gate electrode GEh, respectively.

In addition, by using the gate insulating layer GXh and the gate electrode GEh as a mask, impurity of a predetermined conductivity type is injected into the semiconductor layer DBb, and the source/drain region SDh is formed on lower end portions of the gate insulating layer GXh and the gate electrode GEh, in the X direction.

In addition, an insulating layer LLb that covers the gate insulating layer GXh and the gate electrode GEh is formed on the semiconductor layer DBb. The insulating layer LLb is, for example, a silicon oxide layer, a silicon nitride layer, or a silicon oxynitride layer or has a multi-layer structure where some of the layers are combined, and is a layer that is subsequently patterned to form the liner layer LLh of the transistor TRh.

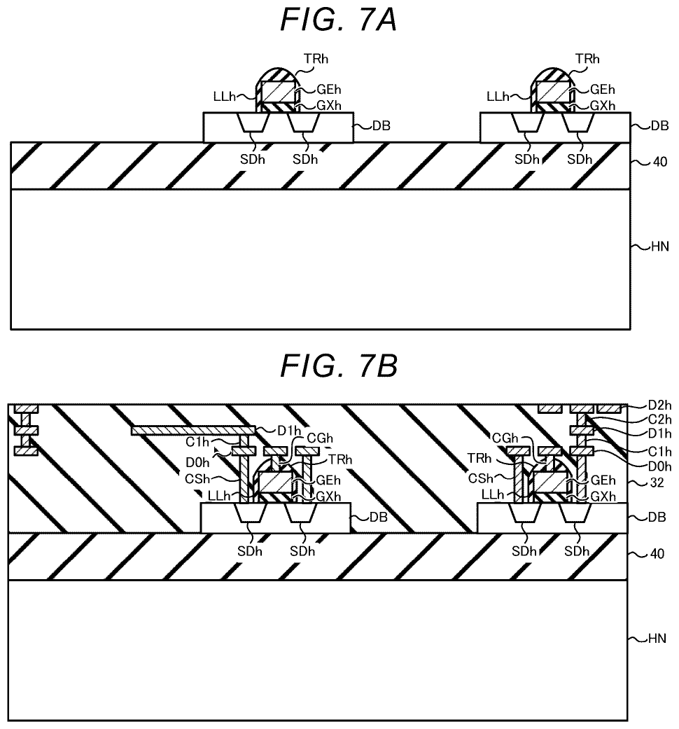

As illustrated in FIG. 7A, the insulating layer LLb is patterned to form the liner layer LLh that covers the gate insulating layer GXh and the gate electrode GEh. In addition, the semiconductor layer DBb is patterned to form each of the semiconductor layers DB where the transistor TRh is disposed.

As illustrated in FIG. 7B, while appropriately forming the insulating layer 32 that covers the semiconductor layers DB and the transistors TRh on the insulating layer 40 of the supporting substrate HN, the contacts CSh and CGh, the wiring layer D0h, the via C1h, the wiring layer D1h, the via C2h, and the wiring layer D2h are sequentially formed in the insulating layer 32. At this time, the wiring layers and the like that establish connection between the transistors TRv on the semiconductor substrate SB and the contact C3 formed in the same hierarchy as the stacked body LM may be formed in the insulating layer 32.

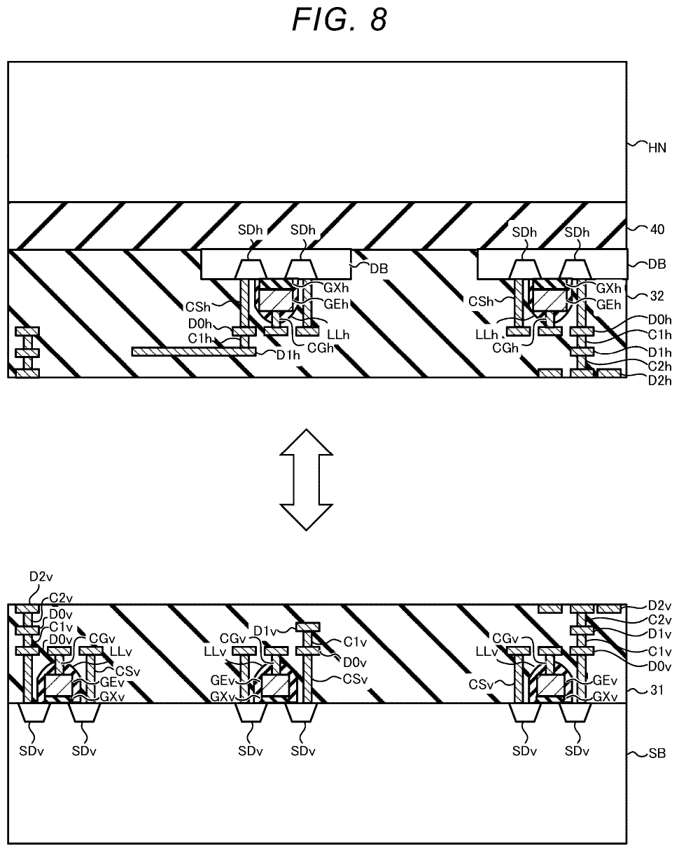

As illustrated in FIG. 8, the semiconductor substrate SB where the transistors TRv are formed and the supporting substrate HN where the transistors TRh are formed are disposed such that the transistors TRv and TRh face each other, and the semiconductor substrate SB and the supporting substrate HN are bonded to each other. The transistors TRv on the semiconductor substrate SB can be formed using the same method as that of the transistors TRv on the semiconductor layers DB.

That is, the gate insulating layer GXv and the gate electrode GEv are formed in this order on the semiconductor substrate SB, the source/drain region SDv is formed on the semiconductor substrate SB by using the gate insulating layer GXv and the gate electrode GEv as a mask, and the liner layer LLv that covers the gate insulating layer GXv and the gate electrode GEv is formed. As a result, the transistor TRv is formed.

In addition, while appropriately forming the insulating layer 31 that covers the transistor TRv, the contacts CSv and CGv, the wiring layer D0v, the via C1v, the wiring layer D1v, the via C2v, and the wiring layer D2v are sequentially formed in the insulating layer 31.

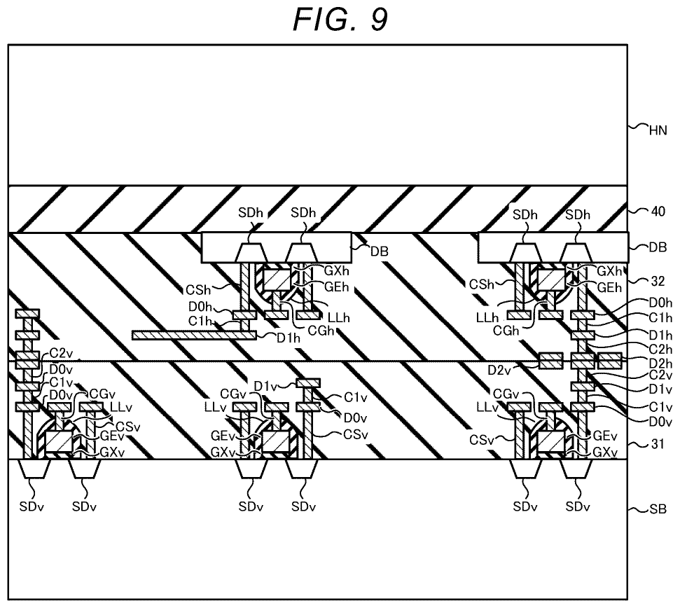

As illustrated in FIG. 9, when the semiconductor substrate SB and the supporting substrate HN are bonded, the insulating layers 31 and 32 formed on the semiconductor substrate SB and the supporting substrate HN, respectively, are joined. The insulating layers 31 and 32 can be joined, for example, by activating the surfaces thereof in advance through a plasma treatment or the like.

In addition, when the insulating layers 31 and 32 are joined, the semiconductor substrate SB and the supporting substrate HN are aligned such that the wiring layers D2v and D2h that are connected to the transistors TRv and TRh and are led out to the surfaces of the insulating layers 31 and 32 overlap each other in the up-down direction.

By executing an annealing treatment after joining the insulating layers 31 and 32, the wiring layers D2v and D2h are joined, for example, through Cu—Cu bonding. As a result, the supporting substrate HN and the semiconductor substrate SB are bonded. A bonded product including the supporting substrate HN and the semiconductor substrate SB will also be referred to as a bonded substrate.

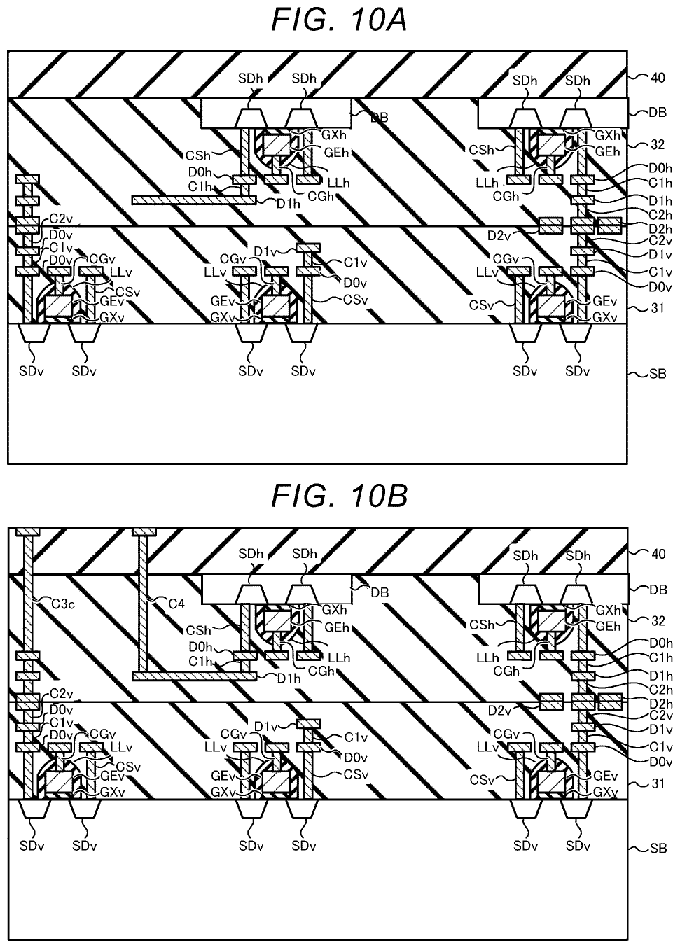

As illustrated in FIG. 10A, the supporting substrate HN is removed from the bonded substrate including the supporting substrate HN and the semiconductor substrate SB to expose the insulating layer 40. After the removal of the supporting substrate HN, the semiconductor substrate SB also functions as a supporting substrate that supports the overall configuration of the transistors TRv and TRh and the like.

As illustrated in FIG. 10B, a contact C3c that penetrates the insulating layers 40 and 32 from the insulating layer 40 side exposed by removing the supporting substrate HN, extends in the insulating layer 31, and reaches the wiring layer D2v electrically connected to the transistor TRv is formed. In addition, the contact C4 that penetrates the insulating layer 40 from the insulating layer 40 side, extends in the insulating layer 32, and reaches the wiring layer D2h electrically connected to the transistor TRh is formed. An electrode pad or the like is provided in each of upper end portions of the contacts C3c and C4.

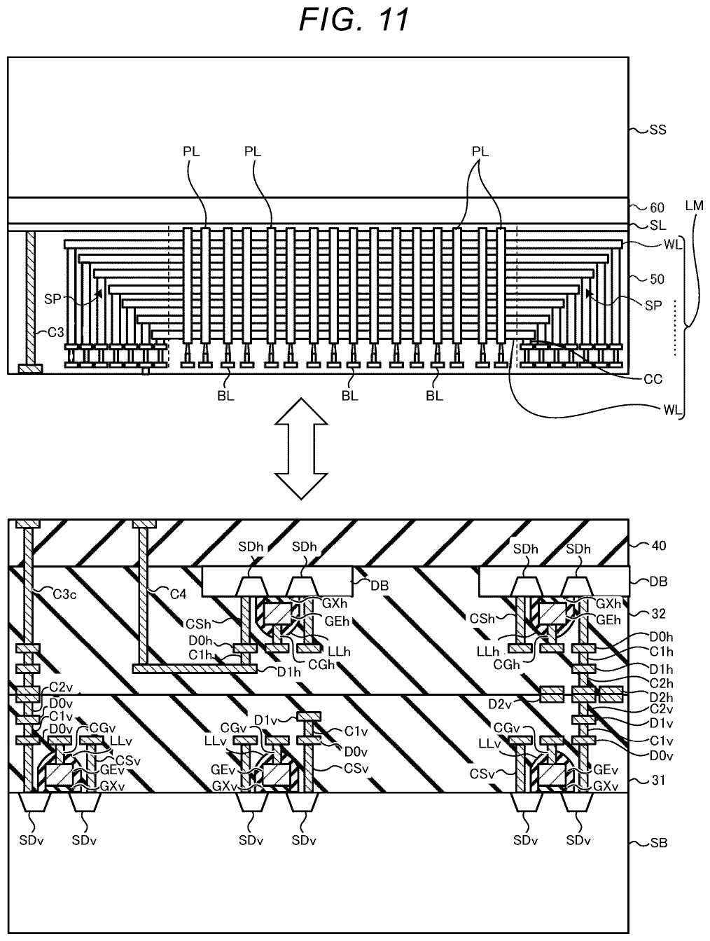

As illustrated in FIG. 11, a supporting substrate SS where the stacked body LM including the pillar PL and the contact CC and the like is formed and the semiconductor substrate SB where the transistors TRv and TRh are stacked in multiple layers are disposed such that the stacked body LM and the transistors TRv and TRh face each other, and the supporting substrate SS and the semiconductor substrate SB are bonded. Here, the stacked body LM and the like including the pillar PL and the contact CC and the like can be formed as follows.

That is, the supporting substrate SS that is a semiconductor substrate such as a silicon substrate, an insulating substrate such as a ceramic substrate, or a conductive substrate or the like is prepared. In addition, the insulating layer 60 and the source line SL are formed in this order on the supporting substrate SS, and a plurality of sacrifice layers (not illustrated) are stacked on the source line SL distant from each other. The plurality of sacrifice layers are subsequently replaced with conductive layers such as tungsten layers to form, for example, silicon nitride layers that function as the word lines WL and the like.

Both end portions of the plurality of sacrifice layers in the X direction are processed stepwise to form the step portion SP, and the entirety of the step portion SP is covered with the insulating layer 50. In addition, the plurality of pillars PL that penetrate the plurality of sacrifice layers and reach the source line SL are formed, and the bit lines BL are formed in the insulating layer 50 above the pillars PL and connected to the pillars PL. In addition, the plurality of sacrifice layers are replaced with conductive layers such as tungsten layers to form the stacked body LM including the plurality of word lines WL and the like. In addition, the contact CC that penetrates the insulating layer 50 covering the stacked body LM and is connected to each of the word lines WL and the like is formed in the step portion SP of the stacked body LM. In addition, the contact C3 that penetrates the insulating layer 50 and reaches the source line SL is formed outside the stacked body LM in the X direction.

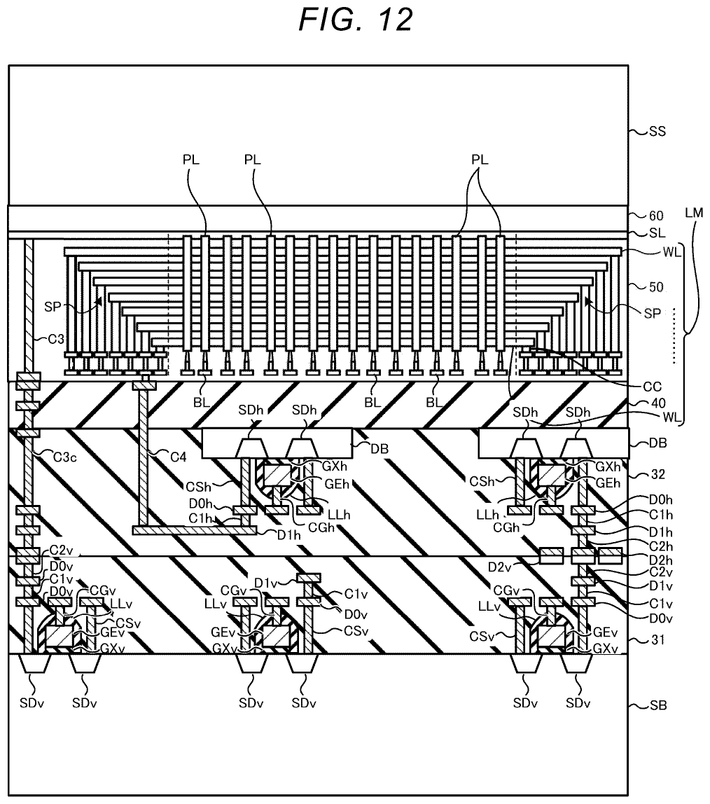

As illustrated in FIG. 12, the semiconductor substrate SB and the supporting substrate SS can be bonded using the same method as that of bonding the semiconductor substrate SB and the supporting substrate HN described above.

That is, the insulating layers 40 and 50 formed on the semiconductor substrate SB and the supporting substrate SS, respectively, are joined. The insulating layers 40 and 50 can be joined, for example, by activating the surfaces thereof in advance through a plasma treatment or the like.

In addition, when the insulating layers 40 and 50 joined, the semiconductor substrate SB and the supporting substrate SS are aligned such that the contacts C3c and C4 that are connected to the transistors TRv and TRh and are led out to the surface of the insulating layer 40, respectively, and the contacts C3 and CC that are formed on the stacked body LM side overlap each other in the up-down direction.

By executing an annealing treatment after joining the insulating layers 40 and 50, the contacts C3c and C3 and the contacts C4 and CC are joined, for example, through Cu—Cu bonding. As a result, the supporting substrate SS and the semiconductor substrate SB are bonded.

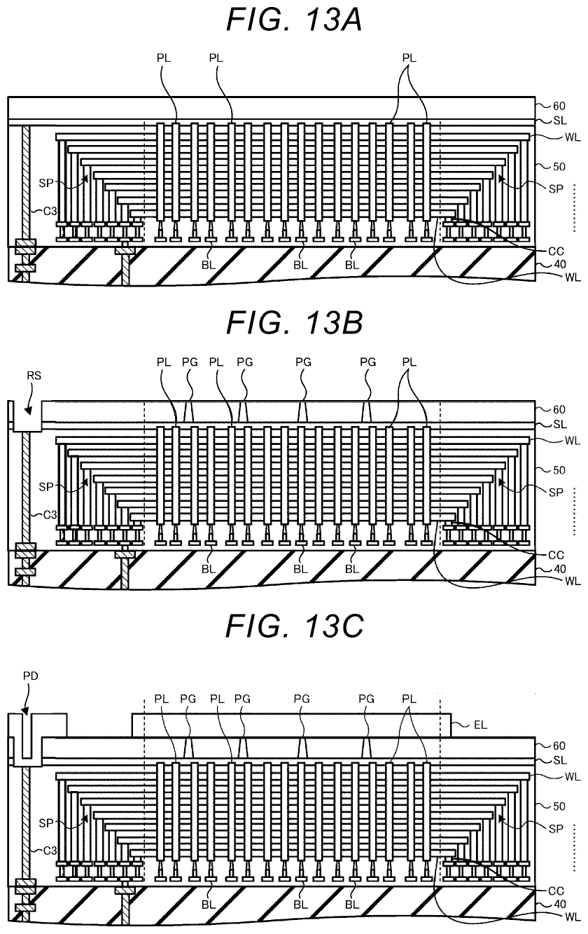

As illustrated in FIG. 13A, the supporting substrate SS is removed to expose the insulating layer 60. Hereinafter, FIGS. 13A to 13C do not illustrate the configuration below the insulating layer 40.

As illustrated in FIG. 13B, the plurality of plugs PG that penetrate the exposed insulating layer 60 and reach the source line SL are formed. In addition, a part of the insulating layer 60 and the source line SL is removed to form a recess portion RS, and the contact C3 is exposed from a bottom surface of the recess portion RS.

As illustrated in FIG. 13C, a conductive layer that covers the insulating layer 60 is formed and patterned to form the electrode layer EL. The electrode layer EL is also formed in the above-described recess portion RS such that the pad region PD connected to the contact C3 is formed.

As a result, the semiconductor device 1 is manufactured.

A semiconductor device such as a three-dimensional nonvolatile memory includes a peripheral circuit that controls the electrical operation of memory cells. The peripheral circuit includes a plurality of transistors formed on a semiconductor substrate. An increase in the storage capacity of the semiconductor device and miniaturization are required, and the number of transistors in the peripheral circuit increases accordingly. Accordingly, by forming transistors on each of a plurality of semiconductor substrates and bonding the semiconductor substrates, an attempt to form the peripheral circuit where the plurality of transistors are stacked in multiple layers is made.

However, when the transistors formed on the semiconductor substrate on the lower layer side, that is, the side away from the stacked body where the pillar and the like are formed, are electrically connected to the electrode layer above the stacked body, contacts that penetrate the semiconductor substrate on the upper layer side need to be formed. In this case, a parasitic capacitance is generated between the contact and the semiconductor substrate, and there is a concern such as a decrease in the quality of signal transmission to the transistor through the contact and a decrease in the transmission rate.

In addition, when the plurality of semiconductor substrates where the transistors are individually formed are bonded, in order to electrically connect the transistors formed in multiple layers to each other, it is preferable that the semiconductor substrates are bonded such that the transistors of the upper and lower layers face each other. In this case, even when the transistor formed on the semiconductor substrate on the upper layer side is electrically connected to the configuration on the stacked body side, a contact that penetrates the semiconductor substrate on the upper layer side needs to be formed, and a decrease in the quality of signal transmission, a decrease in the transmission rate, and the like may occur.

The semiconductor device 1 described above includes the transistor TRv provided on the semiconductor substrate SB and the transistor TRh provided on the side of the semiconductor layer DB facing the semiconductor substrate SB. As a result, by stacking the transistors TRv and TRh in multiple layers, the peripheral circuit CBA including the transistors TRv and TRh of the number corresponding to the semiconductor device 1 that has an increased storage capacity and is miniaturized can be configured.

The semiconductor device 1 includes: the semiconductor layer DB provided above the semiconductor substrate SB and having a smaller area than the semiconductor substrate SB; and the contact C3c penetrating the insulating layer 40 from the transistor TRv and extending upward at a position where the contact C3c does not overlap the semiconductor layer DB in the up-down direction.

This way, the transistor TRh on the upper layer side is formed on the semiconductor layer DB having a smaller area. Therefore, the transistor TRv formed on the semiconductor substrate SB on the lower layer side of the semiconductor layer DB can be connected to the configuration on the stacked body LM side through the contact C3c and the like, for example, without penetrating the semiconductor substrate and the like on the upper layer side. Accordingly, the plurality of transistors TRv and TRh can be stacked while reducing an increase in parasitic capacitance.

In the insulating layer 40 of the semiconductor device 1, a carbon concentration at least on the side in contact with the semiconductor layer DB is 1×1018 atoms/cm3 or less. As a result, a leakage current from the semiconductor layer DB where the transistor TRh is provided can be reduced.

In the semiconductor device 1, the transistor TRv is a low voltage MOS transistor, and the transistor TRh is a high voltage MOS transistor. Accordingly, the transistor TRv for a low voltage that requires a high speed operation for some uses is provided on the semiconductor substrate SB having a higher carrier mobility such that the operation performance of the transistor TRv can be improved.

The insulating layer 40 and the semiconductor layer DBb are formed in this order on the supporting substrate HN to form the transistor TRh. However, the transistor TRh can also be formed using a silicon on insulator (SOI) substrate. The SOI substrate is a substrate where a monocrystalline silicon layer is formed on a silicon substrate or the like called a handle substrate through a silicon oxide layer called a buried oxide (BOX) layer.

When the SOI substrate is used, the transistor TRh can be formed on the monocrystalline silicon layer. In this case, the handle substrate of the SOI substrate, the BOX layer, and the monocrystalline silicon layer correspond to the supporting substrate HN, the insulating layer 40, and the semiconductor layer DBb, respectively.

### Modification Examples

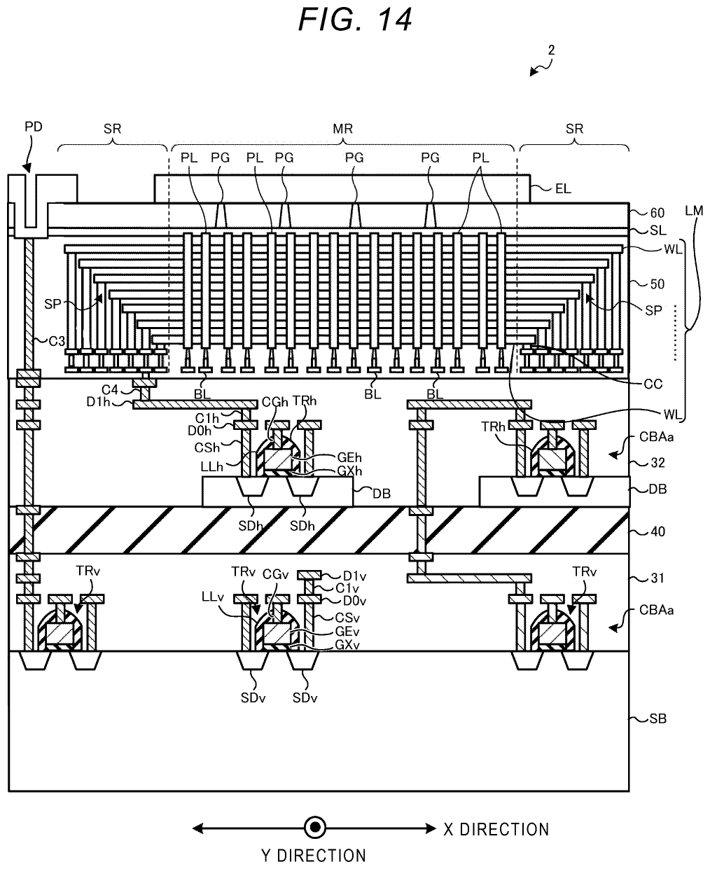

Next, a semiconductor device 2 according to a modification example will be described using FIG. 14. The semiconductor device 2 according to the modification example is different from the semiconductor device 1 described above in the directions of the transistors TRv and TRh.

FIG. 14 is a cross-sectional view illustrating a configuration example of the semiconductor device 2 according to the modification example. It should be noted that FIG. 14 does not illustrate hatching of a partial configuration in consideration of easy understanding of the drawing. In addition, in FIG. 14, the same components as those of semiconductor device 1 will be represented by the same reference numerals, and the description thereof will not be repeated.

As illustrated in FIG. 14, the semiconductor device 2 according to the modification example also includes a peripheral circuit CBAa including the transistors TRv and TRh that are stacked in multiple layers. It should be noted that the insulating layer 40 is interposed between the transistor TRv and the transistor TRh, and the transistor TRv and the transistor TRh do not face each other in the up-down direction.

That is, a bonding surface of the semiconductor substrate SB where the transistor TRv is formed and the semiconductor layer DB where the transistor TRh is formed is an interface between the insulating layer 31 that covers the semiconductor substrate SB and the insulating layer 40 provided on a lower surface of the semiconductor layer DB.

In addition, when the directions of the transistors TRv and TRh in the up-down direction are the same and the transistors TRv and TRh are electrically connected to each other, a contact or the like that penetrates the insulating layer 40 can be provided. Even in this case, the semiconductor substrate or the like is not interposed between the transistors TRv and TRh, and thus a parasitic capacitance can be prevented from being generated.

The semiconductor device 2 according to the modification example can be obtained, for example, using the following manufacturing method.

That is, the insulating layer 40 and the semiconductor layer DB are formed in this order, and the supporting substrate HN where the transistors TRh are formed and the supporting substrate SS where the stacked body LM or the like including the pillar PL and the contact CC and the like is formed are further bonded on the semiconductor layer DB by joining the insulating layer 32 that covers the transistor TRh and the insulating layer 50 that covers the stacked body LM or the like.

In addition, the supporting substrate HN bonded to the supporting substrate SS is removed to expose the insulating layer 40. In addition, the semiconductor substrate SB where the transistor TRv is formed and the supporting substrate SS including the stacked body LM and the transistor TRh and the like are bonded by joining the insulating layer 31 that covers the transistor TRv and the insulating layer 40 on the supporting substrate HN side.

Hereinafter, the semiconductor device 2 according to the modification example is manufactured by executing the treatment illustrated in FIG. 13.

This way, in the method of stacking the plurality of transistors TRv and TRh in multiple stages such that the directions thereof in the up-down direction are the same, the transistors TRv and TRh can also be stacked in three or more stages.

In the semiconductor device 2 according to the modification example, the same effects as those of the above-described embodiment are exhibited.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor substrate;
a first transistor on the semiconductor substrate;
an insulating layer above the semiconductor substrate in a first direction;
a semiconductor layer provided on the insulating layer and partially overlapping the semiconductor substrate and the insulating layer in the first direction;
a second transistor on the semiconductor layer;
a first contact penetrating the insulating layer in the first direction such that the first contact is not in contact with the semiconductor layer;
a second contact extending parallel to the first contact; and
a memory cell array provided above the insulating layer and electrically connected to the second transistor through the second contact.

2. The semiconductor device according to claim 1, wherein
a carbon concentration of a first portion of the insulating layer that contacts the semiconductor layer is 1×1018 atoms/cm3 or less.

3. The semiconductor device according to claim 1, wherein
the first transistor includes a first gate electrode and a first gate insulating layer, and
the second transistor includes:
a second gate electrode, a gate length of which is longer than the first gate electrode, and
a second gate insulating layer that is thicker than the first gate insulating layer.

4. The semiconductor device according to claim 1, wherein
a threshold voltage of the first transistor is lower than the second transistor.

5. The semiconductor device according to claim 4, wherein
the first transistor is a low voltage (LV) MOS transistor, and the second transistor is a high voltage (HV) MOS transistor.

6. The semiconductor device according to claim 1, wherein
the memory cell array includes a plurality of conductive layers that are arranged and separated from each other in a first direction, and a pillar penetrating the conductive layers in the first direction, and
a memory cell is formed at an intersection between the pillar and one of the conductive layers.

7. The semiconductor device according to claim 1, wherein
the insulating layer is between the memory cell array and the semiconductor layer.

8. The semiconductor device according to claim 7, wherein
the second contact penetrates the insulating layer.

9. The semiconductor device according to claim 1, wherein:
the insulating layer is between the first and second transistors.

10. The semiconductor device according to claim 1, wherein
the first transistor overlaps the semiconductor layer when viewed from above.

11. A semiconductor device comprising:
a semiconductor substrate;
a first transistor on the semiconductor substrate;
an insulating layer above the semiconductor substrate in a first direction;
a semiconductor layer provided on the insulating layer and partially overlapping the semiconductor substrate and the insulating layer in the first direction;
a second transistor on the semiconductor layer;
a first contact penetrating the insulating layer in the first direction such that the first contact is not in contact with the semiconductor layer;
a second contact extending parallel to the first contact; and
a memory cell array provided above the insulating layer and electrically connected to the second transistor through the second contact, wherein
the insulating layer includes a first portion that contacts an upper surface of the semiconductor layer, and a carbon concentration of the first portion is lower than another portion of the insulating layer.

12. The semiconductor device according to claim 11, wherein the carbon concentration of the first portion is 1×1018 atoms/cm3 or less.

13. The semiconductor device according to claim 11, wherein
the first transistor includes a first gate electrode and a first gate insulating layer, and
the second transistor includes:
a second gate electrode, a gate length of which is longer than the first gate electrode, and
a second gate insulating layer that is thicker than the first gate insulating layer.

14. The semiconductor device according to claim 11, wherein
a threshold voltage of the first transistor is lower than the second transistor.

15. The semiconductor device according to claim 11, wherein
the memory cell array includes a plurality of conductive layers that are arranged and separated from each other in a first direction, and a pillar penetrating the conductive layers in the first direction, and
a memory cell is formed at an intersection between the pillar and one of the conductive layers.

16. A method of manufacturing a semiconductor device, the method comprising:
forming a first transistor on a first semiconductor substrate;
forming a first insulating layer to cover the first transistor on the first semiconductor substrate;
preparing a second semiconductor substrate on which a semiconductor layer is formed through a second insulating layer;
forming a second transistor on the semiconductor layer of the second semiconductor substrate and patterning the semiconductor layer to have a smaller area than the first semiconductor substrate;
forming a third insulating layer to cover the second transistor and the patterned semiconductor layer on the second semiconductor substrate;
forming a bonded substrate by bonding the first and second semiconductor substrates to each other through the first and third insulating layers;
removing the second semiconductor substrate from the bonded substrate; and
forming a contact that penetrates the first and third insulating layers from the first transistor and extends upward such that the contact does not overlap the semiconductor layer when viewed from above.

17. The method according to claim 16, wherein
a carbon concentration of a first portion of the second insulating layer that contacts the semiconductor layer is 1×1018 atoms/cm3 or less.

18. The method according to claim 16, wherein
forming the first transistor includes forming a first gate insulating layer and a first gate electrode, and
forming the second transistor includes:
forming a second gate insulating layer that is thicker than the first gate insulating layer, and
forming a second gate electrode, a gate length of which is longer the first gate electrode.

19. The method according to claim 16, further comprising:
forming a stacked body where a plurality of conductive layers are stacked distant from each other above a supporting substrate;
forming a pillar that extends in the stacked body in a stacking direction of the stacked body; and
bonding the second insulating layer side of the first semiconductor substrate that includes the first and second transistors and the stacked body side of the supporting substrate where the stacked body and the pillar are formed to each other and removing the supporting substrate.

20. The method according to claim 16, wherein
the second semiconductor substrate is an SOI substrate.
